(19) United States
(12) Patent Application Publication
(10) Pub. No.: US 2006/0024896 A1
(43) Pub. Date: Feb. 2, 2006

(54) METHOD FOR FABRICATING METAL-OXIDE-SEMICONDUCTOR TRANSISTOR WITH SELECTIVE EPITAXIAL GROWTH FILM

(76) Inventors: Kuo-Tai Huang, Hsin-Chu City (TW); Ya-Lun Cheng, Taipei City (TW); Yi-Ying Chiang, Taipei City (TW)

Correspondence Address: NORTH AMERICA INTELLECTUAL PROPERTY CORPORATION, P.O. BOX 506, MERRIFIELD, VA, 22116, US

(21) Appl. No.: 11/163,317

(22) Filed: Oct. 14, 2005

Related U.S. Application Data
(63) Continuation of application No. 10/462,688, filed on Jun. 17, 2003.

(51) Int. Cl. H01L 21/336; H01L 21/44

(52) U.S. Cl. 438/300; 438/301; 438/607; 438/305

(57) ABSTRACT

A method for forming MOS transistor with improved resistance to HF attack during a pre-SEG clean process is disclosed. The MOS transistor encompasses a substrate having a gate with sidewalls. The gate is patterned on the main surface of the substrate. Source/drain doping regions are formed on opposite sides of the gate electrode in the main surface of the semiconductor substrate. A gate oxide layer is disposed underneath the gate electrode. A surface-nitridized silicon oxide liner covers the two sidewalls of the gate electrode. The surface nitridized silicon oxide liner further overlies lightly doped drain (LDD) regions in close proximity to the gate electrode. A silicon nitride spacer is disposed on the surface-nitridized silicon oxide liner. An elevated selective epitaxial growth (SEG) film is grown on the S/D regions and top of the gate electrode. A silicide layer formed from the elevated SEG film.

### CROSS REFERENCE TO RELATED APPLICATIONS

This is a continuation application of U.S. patent application Ser. No. 10/462,688 filed Jun. 17, 2003.

### BACKGROUND OF THE INVENTION

1. Field of the Invention

The present invention relates generally to a metal-oxide-semiconductor (MOS) transistor and a fabrication method thereof. More specifically, the present invention relates to an improved method for fabricating a MOS transistor with selective epitaxial growth (SEG) films, which are formed on exposed gate, source, and drain regions. The metal-oxide-semiconductor (MOS) transistor of this invention has improved resistance to HF attack during a pre-SEG clean process.

b 2. Description of the Prior Art

Continued device scaling demands that source/drain junctions become thinner and thinner. A potential problem when forming a contact to these very shallow junctions is that contacts are traditionally made with silicides, typically TiSi₂ or WSi₂. A thin layer of the metal (Ti or W) is deposited on top of the silicon by sputtering, and the silicide is formed by reacting the metal and the underlying silicon with a rapid thermal processing (RTP) step. Through this process, a small amount of the silicon of the source/drain is consumed. Though small, this consumption of silicon is increasingly a larger percentage of the overall thickness of the source or drain. Although the silicide thickness has been scaled down (to avoid increased leakage from the proximity of the silicide/silicon interface to the junction depletion region), the amount of scaling is limited. The bottom line is that the combination of a shallow junction and a thin silicide contact can lead to unacceptably high resistance in the device. According to the International Technology Roadmap for Semiconductors (ITRS), the parasitic device resistance should be no more than 10% of the channel resistance for the 100 nm technology node and beyond.

Elevated source/drains provide a way to avoid the parasitic resistance increase while still maintaining shallow junctions. Elevated source/drains are fabricated by raising the level of the source and drain by selective silicon deposition. The extra silicon increases the process margin for the silicide process and extends the latitude for contact junction design. To maintain a similar crystalline structure, the extra silicon is “grown” by silicon epitaxy, which is known as Selective Epitaxial Growth (SEG).

Please refer to FIG. 1 to FIG. 7. FIG. 1 to FIG. 7 are schematic cross-sectional diagrams illustrating a prior art method of fabricating a MOS transistor having raised SEG source/drain. As shown in FIG. 1, a polysilicon gate structure 101 is defined on a semiconductor substrate 100 using conventional chemical vapor deposition (CVD) and etching processes known in the art. The gate structure 101 is insulated from the semiconductor substrate 100 by a thin gate oxide 102. As shown in FIG. 2, a CVD silicon oxide layer 104 is deposited over the gate structure 101. As shown in FIG. 3, an etching process is carried out to etch back the CVD silicon oxide layer 104 to form an offset spacer 106 on sidewalls of the of gate structure 101. Thereafter, using the gate structure 101 and the offset spacer 106 as an implantation mask, lightly doped drain (LDD) regions 108 are formed on both sides of the gate structure 101 in the semiconductor substrate 100.

As shown in FIG. 4, a liner oxide layer 121 having a thickness of about 100-150 angstroms is deposited over the entire surface of the semiconductor substrate 100 by conventional CVD method. Subsequently, a silicon nitride layer 122 of about 500-1000 angstroms is deposited on the liner oxide layer 121. As shown in FIG. 5, the liner oxide layer 121 and the silicon nitride layer 122 are anisotropically etched back to form a spacer structure 124 on each sidewall of the gate structure 101. At this phase, the upper surface of the gate structure 101 and a portion of the LDD regions 108 are exposed. Subsequently, using the gate 101 and the spacer structure 124 as a doping mask, ions such as phosphorus or arsenic are implanted into the semiconductor substrate 100, generally followed by a thermal driving at a temperature of about 900-1000° C., to form source/drain doping regions 109.

The semiconductor substrate 100 is now ready to be subjected to an SEG process to form raised source and drain. It is appreciated that before implementing the SEG process, a thin native oxide layer or oxide residuals over the exposed silicon surface must be removed. The removal of the native oxide layer, which is also known as a pre-SEG clean step, is usually accomplished by dipping the substrate in diluted hydrofluoric acid solution (HF).

Typically, an HF concentration of 400:1, 200:1, or 100:1 (v/v) is used. It is often desirable to use diluted HF solution with a higher concentration since it results in a cleaner silicon surface for the following SEG process and thus a better SEG process window. However, as shown in FIG. 6, the pre-SEG clean step causes sever undercuts 130. As shown in FIG. 7, a selective epitaxial growth (SEG) film 140 is selectively formed on the exposed upper surface of the gate structure 101 and the exposed LDD regions 108. Due to the existence of the undercuts 130, the SEG film 140 might extend under the nitride spacer structure 124 and, in some cases, void 142 might be observed. In a worst case, the undercuts 130 cause bridge between the source and gate or between the drain and gate during following silicidation process.

### SUMMARY OF THE INVENTION

It is one objective of this invention to provide an improved method of fabricating a MOS transistor with raised source/drain, in which the undercut is avoided during pre-SEG clean.

Briefly summarized, one preferred embodiment of the present invention discloses a method for fabricating a metal-oxide-semiconductor (MOS) transistor, including the following steps:

(a) providing a semiconductor substrate having a main surface;

(b) forming a gate oxide layer on the main surface of the semiconductor substrate;

(c) forming a gate electrode on the gate oxide layer, the gate electrode having two sidewalls;

(d) forming a liner on the sidewalls of the gate electrode;

(e) transforming an upper layer of the liner into an silicon oxy-nitride layer thereby improving resistance to hydrogen fluoride (HF) attack during a subsequent pre-SEG clean process and thus eliminating spacer undercut;

(f) forming a silicon nitride spacer on the liner;

(g) forming a source/drain doping region on opposite sides of the gate electrode in the main surface of the semiconductor substrate;

(h) pre-cleaning surface of the source/drain doping region by using hydrogen fluoride as an etchant;

(i) selectively growing epitaxial film on the source/drain doping region; and

(j) siliciding the epitaxial film grown on the source/drain doping region.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 to FIG. 7 are schematic cross-sectional diagrams illustrating a prior art method of fabricating a MOS transistor having SEG source/drain.

FIG. 8 to FIG. 15 are schematic cross-sectional diagrams illustrating a method of fabricating a MOS transistor having SEG source/drain according to one preferred embodiment of the present invention.

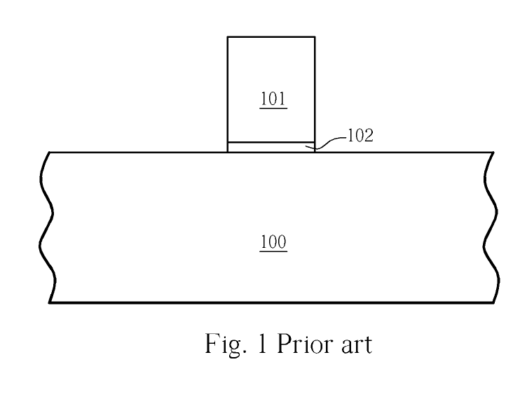

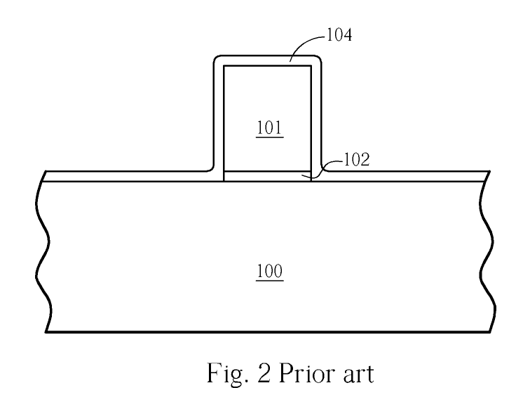

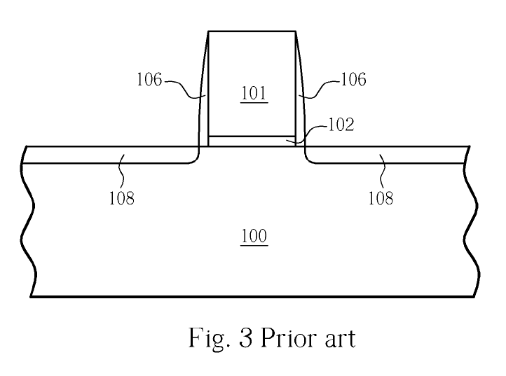

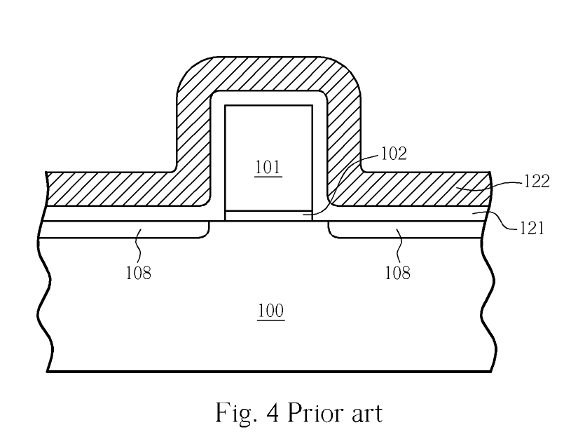

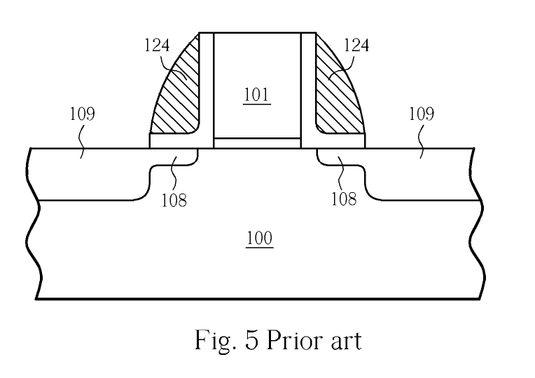

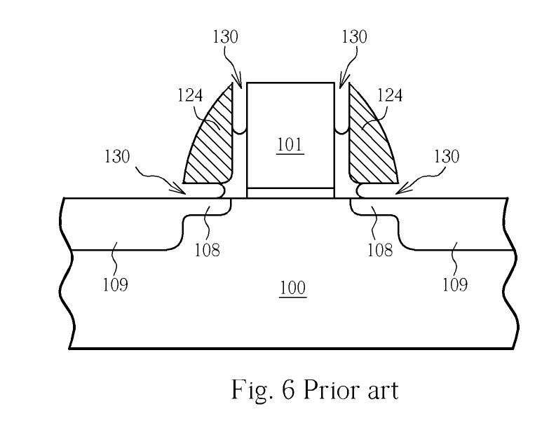

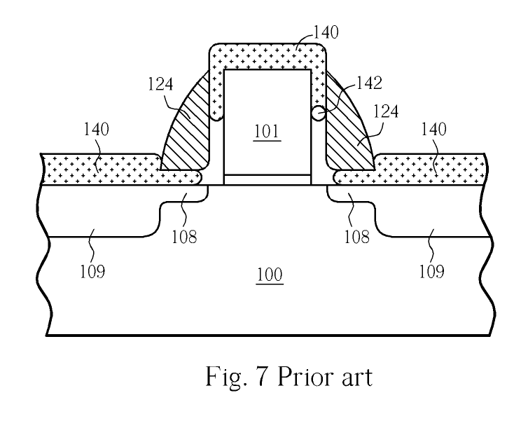

### DETAILED DESCRIPTION

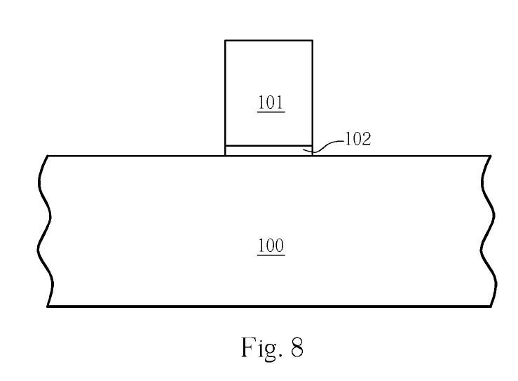

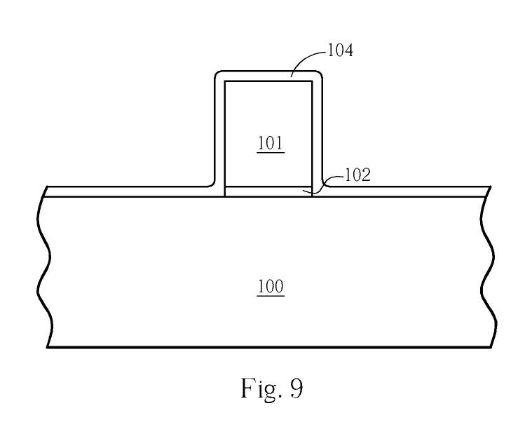

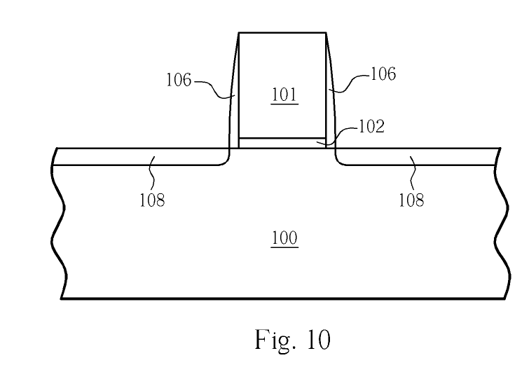

Please refer to FIG. 8 to FIG. 15. FIG. 8 to FIG. 15 are schematic cross-sectional diagrams illustrating an improved method of fabricating a MOS transistor having SEG source/drain according to this invention, in which like reference numerals designate similar or corresponding elements, regions, and portions. As shown in FIG. 8, likewise, a polysilicon gate structure 101 is defined on a semiconductor substrate 100 using conventional chemical vapor deposition (CVD) and etching processes known in the art. The gate structure 101 is insulated from the underlying semiconductor substrate 100 by a thin gate oxide 102. As shown in FIG. 9, a CVD silicon oxide layer 104 is deposited over the gate structure 101. As shown in FIG. 10, an etching process is carried out to etch back the CVD silicon oxide layer 104 to form an offset spacer 106 on sidewalls of the of gate structure 101. Thereafter, using the gate structure 101 and the offset spacer 106 as an implantation mask, lightly doped drain (LDD) regions 108 are formed on both sides of the gate structure 101 in the semiconductor substrate 100. It is appreciated that the formation of the offset spacer 106 is optional. In some cases, the formation of the offset spacer 106 is omitted.

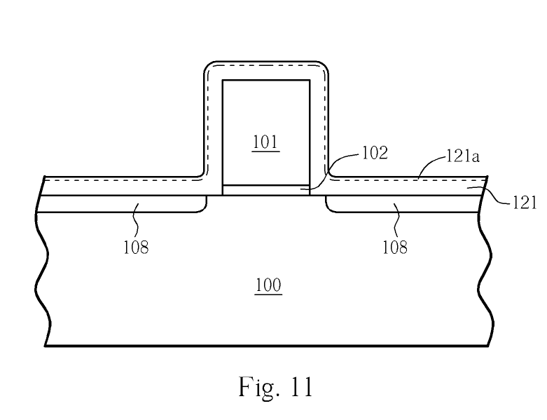

As shown in FIG. 11, in accordance with one preferred embodiment of the present invention, a liner oxide layer 121 having a thickness of about 30-150 angstroms, preferably 100 angstroms, is deposited over the entire surface of the semiconductor substrate 100 by conventional CVD method. It is noted that since the offset spacer 106 and the liner oxide layer 121 are both formed from silicon oxide, the offset spacer 106 is not explicitly shown in the following figures. Subsequently, a nitridation process is carried out to form a thin silicon oxy-nitride film 121a (5-80 angstroms) on the surface of the liner oxide layer 121. The silicon oxy-nitride film 121a increases the resistance of the transistor to the subsequent HF attack of the pre-SEG clean. The nitridation process may be remote plasma nitridation (RPN), decouple plasma nitridation (DPN), slot plate antenna (SPA), modified magnetron technology (MMT), or ammonia (NH₃) soak, but not limited thereto. By way of example, the RPN process can be carried out by using a N₂/He carrier gas mixture at a reaction temperature of about 650° C. under a pressure of about 1 Torr-3 Torr. The DPN process can be carried out by using a N₂/He carrier gas mixture at a reaction temperature of about 100° C. under a pressure of about 5 mTorr-120 mTorr. The NH₃ soak can be carried out at a temperature of between 500 and 700° C. for 15-60 seconds.

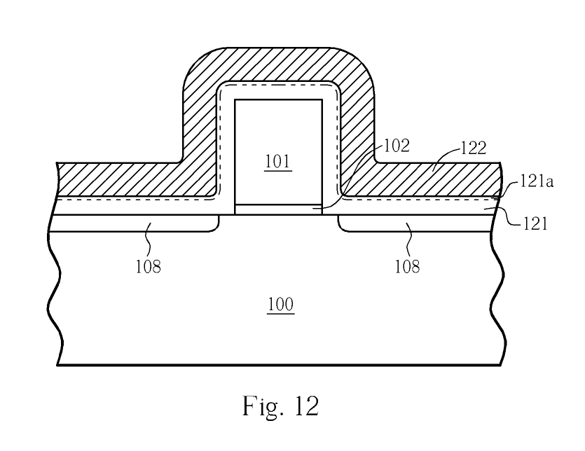

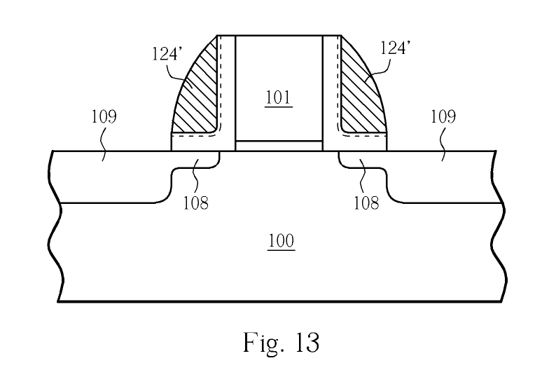

As shown in FIG. 12, a silicon nitride layer 122 of about 300-1000 angstroms is deposited on the silicon oxy-nitride film 121a. As shown in FIG. 13, the liner oxide layer 121, the silicon oxy-nitride film 121a, and the silicon nitride layer 122 are anisotropically etched back to form a spacer structure 124′ on each sidewall of the gate structure 101. At this phase, the upper surface of the gate structure 101 and a portion of the LDD regions 108 are exposed. Subsequently, using the gate 101 and the spacer structure 124′ as a doping mask, ions such as phosphorus or arsenic are implanted into the semiconductor substrate 100, generally followed by a thermal driving at a temperature of about 900-1000° C., to form source/drain doping regions 109. The semiconductor substrate 100 is then ready to be subjected to an SEG process to form raised source and drain. Likewise, a pre-SEG clean step is executed prior to the SEG process.

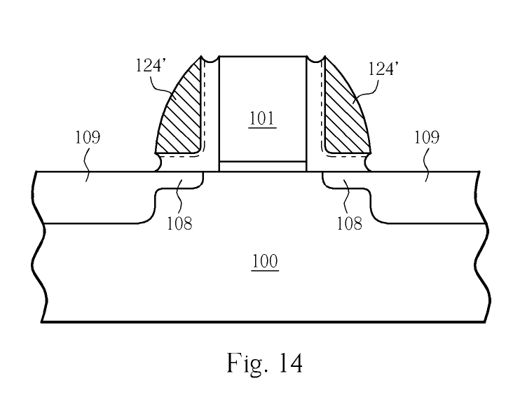

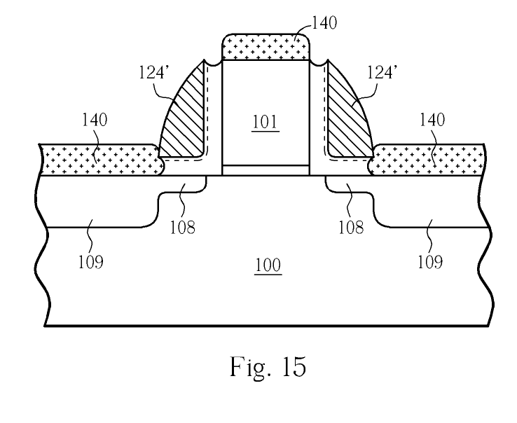

Diluted HF solution with a concentration of 400:1 (v/v) is used. As mentioned, it is often desirable to use diluted HF solution with a concentration as high as possible since higher concentration diluted HF solution results in a cleaner silicon surface for the following SEG process and thus a better SEG process window. FIG. 14 depicts the cross-sectional view of the transistor in process after the pre-SEG clean. The risk of causing undercuts due to the use of high concentration diluted HF solution is eliminated, thereby increasing the process window of the following SEG process. As shown in FIG. 15, a selective epitaxial growth (SEG) film 140 is selectively formed on the exposed upper surface of the gate structure 101 and the exposed S/D doping regions 109. A silicidation process is then carried out to form silicide layer on the SEG film 140.

In contrast to the prior art, the present invention provides an improved MOS transistor having a larger SEG process window. The oxy-nitride film 121a increases the resistance of the transistor to the subsequent HF attack during the pre-SEG clean process. The undercut phenomenon is eliminated due to the fact that the effective liner oxide thickness is reduced down to about 20-50 angstroms. The reduced liner oxide thickness has capillarity nature that inhibits the attack of HF during the pre-SEG clean process.

In accordance with another preferred embodiment of the present, the step of forming the silicon oxy-nitride film 121a may be omitted. Instead of forming the CVD liner oxide layer 121, a 30-100 angstrom thick atomic layer deposition (ALD) oxide is formed prior to the deposition of the silicon nitride layer 122. The thin ALD oxide film, which can be formed by methods known in the art, has denser oxide structure than that of traditional CVD oxide to resist HF attack. Further, a 30-angstrom thick ALD oxide film results in capillarity effect thereby preventing the undercut phenomenon.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a metal-oxide-semiconductor (MOS) transistor, comprising:
providing a semiconductor substrate having a main surface;
forming a gate oxide layer on the main surface of the semiconductor substrate;
forming a gate electrode on the gate oxide layer, the gate electrode having two sidewalls;
forming a liner on the sidewalls of the gate electrode;
transforming an upper layer of the liner into an silicon oxy-nitride layer thereby improving resistance to hydrogen fluoride (HF) attack during a subsequent pre-SEG clean process and thus eliminating spacer undercut;
forming a silicon nitride spacer on the liner;
forming a source/drain doping region on opposite sides of the gate electrode in the main surface of the semiconductor substrate;
pre-cleaning surface of the source/drain doping region by using hydrogen fluoride as an etchant;
selectively growing epitaxial film on the source/drain doping region; and
siliciding the epitaxial film grown on the source/drain doping region.

2. The method according to claim 1 wherein the liner further overlies a lightly doped drain (LDD) region in close proximity to the gate electrode, wherein the LDD region is between the gate electrode sidewall and the source/drain doping region.

3. The method according to claim 1 wherein the liner consists of a layer of silicon dioxide, and wherein the silicon nitride spacer is formed on the silicon oxy-nitride layer.

4. The method according to claim 1 wherein the silicon oxy-nitride layer has a thickness of about 5-80 angstroms.
